(19) United States
(12) Patent Application Publication
(10) Pub. No.: US 2010/0295047 A1
(43) Pub. Date: Nov. 25, 2010

(54) SEMICONDUCTOR ELEMENT AND METHOD FOR MANUFACTURING THE SAME

(76) Inventors: Masao Moriguchi, Osaka (JP); Yuichi Saito, Osaka (JP); Akihiko Kohno, Osaka (JP)

Correspondence Address: BIRCH STEWART KOLASCH & BIRCH, PO BOX 747, FALLS CHURCH, VA, 22040-0747, US

(21) Appl. No.: 12/864,480

(22) PCT Filed: Jan. 23, 2009
(86) PCT No.: PCT/JP2009/000252

§ 371 Date: Jul. 23, 2010

(30) Foreign Application Priority Data
Jan. 25, 2008 (JP) 2008 015649

(51) Int. Cl. H01L 29/786; H01L 21/336

(52) U.S. Cl. 257/57; 438/158; 257/E21.411; 257/E29.285

(57) ABSTRACT

To provide a semiconductor device which achieves a high ON current and a low OFF current at the same time, and a fabrication method thereof.

A semiconductor device of the present invention includes a glass substrate 1, an island-shaped semiconductor layer 4 which includes a first region 4c, a second region 4a, and a third region 4c, a source region 5a and a drain region 5b, a source electrode 6a, a drain electrode 6b, and a gate electrode 2 for controlling the conductivity of the first region 4c. The upper surface of the first region 4c is closer to the glass substrate 1 than the upper surfaces of ends of the second region 4a and the third region 4b adjacent to the first region 4c are. The distances between the upper surfaces of the ends of the second region 4a and the third region 4b and the upper surface of the first region 4c along the thickness direction of the semiconductor layer 4 are each independently not less than one time and not more than seven times the thickness of the first region 4b.

### TECHNICAL FIELD

The present invention relates to a semiconductor device and a method for fabricating the semiconductor device.

### BACKGROUND ART

Conventionally, a thin film transistor (hereinafter, abbreviated as “TFT”) has been known as a semiconductor device for driving a pixel of a liquid crystal display device or organic EL display device.

A TFT which has an amorphous channel region, such as amorphous silicon (hereinafter, abbreviated as “a-Si”), has been commonly used. Such a TFT is hereinafter abbreviated as “a-Si TFT”. The mobility of a-Si is about 0.2 to 0.5 cm²/Vs, so that the a-Si TFT has a poor ON characteristic. On the other hand, a-Si has a broad bandgap, so that the value of the leakage current (OFF current) of the a-Si TFT is small. Thus, the a-Si TFT has a disadvantage that the value of the ON current is small, although it has an advantage that the value of the OFF current is small.

On the other hand, a TFT in which at least part of a channel region is constituted of a microcrystalline silicon film (hereinafter, abbreviated as “microcrystalline silicon TFT”) has also been known. Here, the “microcrystalline silicon film” refers to a film in which a crystalline silicon phase and an amorphous silicon phase are mixedly contained.

Since the microcrystalline silicon film contains crystals, the mobility of the channel region of the microcrystalline silicon TFT is 0.7 to 3 cm²/Vs, so that the value of the ON current is large as compared with the a-Si TFT. On the other hand, the microcrystalline silicon film contains a large number of defect levels, so that the state of junction of the channel region that contains a microcrystalline silicon film, the source region, and the drain region (n⁺ Si film) is poor. The microcrystalline silicon film has a lower electric resistance and a narrower bandgap than the a-Si film, and therefore has a larger OFF current. Thus, the microcrystalline silicon TFT can achieve a large ON current as compared with the a-Si TFT but has a disadvantage that the value of the OFF current is also large.

Patent Document 1 discloses that the thickness of the active layer is not more than 100 nm for the purpose of reducing the OFF current of the microcrystalline silicon TFT. In Patent Document 1, an amorphous silicon film which contains an impurity is formed on a microcrystalline silicon film which functions as the active layer, and thereafter, the etching selection ratio of these films is utilized to selectively remove only the amorphous silicon film.

Patent Document 1: Japanese Laid-Open Patent Publication No. 5-304171

### DISCLOSURE OF INVENTION

### Problems to be Solved by the Invention

Patent Document 1 states that the thickness of the microcrystalline silicon film, i.e., the thickness of the channel, is not more than 100 nm. However, the OFF current cannot be reduced only by limiting the thickness of the channel to this range.

Since the etching rate of the amorphous silicon and the etching rate of the microcrystalline silicon are not significantly different from each other, it is practically difficult to selectively etch only the amorphous silicon film. Hence, it is difficult to form the microcrystalline silicon film and the amorphous silicon film into a layered structure, and control the thickness of the channel by utilizing only the difference in the etching rate between these films, as in Patent Document 1.

The present invention was conceived for the purpose of solving the above problems. One of the major objects of the present invention is to provide a semiconductor device which has a small OFF current value and a fabrication method thereof.

### Means for Solving the Problems

A semiconductor device of the present invention includes: a substrate; an island-shaped active layer provided on the substrate, the active layer including a first region, a second region, and a third region, and the second region and the third region being provided on opposite sides of the first region; a first contact layer and a second contact layer, the first contact layer being in contact with an upper surface of the second region of the active layer, and the second contact layer being in contact with an upper surface of the third region of the active layer; a first electrode electrically coupled to the second region via the first contact layer; a second electrode electrically coupled to the third region via the second contact layer; and a gate electrode which is provided to oppose the first region via a gate insulating film for controlling the conductivity of the first region, wherein an upper surface of the first region is closer to the substrate than upper surfaces of ends of the second region and the third region adjacent to the first region are, and distances between the upper surfaces of the ends of the second region and the third region and the upper surface of the first region along a thickness direction of the active layer are each independently not less than one time and not more than seven times a thickness of the first region.

In one embodiment, at least the first region is constituted of a microcrystalline silicon film which has a crystal grain and an amorphous phase.

In one embodiment, a volume fraction of the amorphous phase in the microcrystalline silicon film is not less than 5% and not more than 40%.

In one embodiment, the distances are not less than 60 nm and not more than 140 nm, and the thickness of the first region is not less than 20 nm and not more than 60 nm.

In one embodiment, the ends of the second region and the third region which are adjacent to the first region are composed of a microcrystalline silicon.

In one embodiment, the ends of the second region and the third region which are adjacent to the first region are composed of an amorphous silicon.

In one embodiment, the gate electrode is provided between the active layer and the substrate.

In one embodiment, the gate electrode is provided on a side of the active layer which is opposite to the substrate.

In one embodiment, the active layer includes a first active layer, an intermediate layer, and a second active layer in this order from a substrate side, the first region is constituted of the first active layer and does not include the second active layer, and the second region and the third region are constituted of the first active layer, the intermediate layer, and the second active layer.

In one embodiment, the first active layer and the second active layer are silicon layers, and the intermediate layer is a film composed of a silicon oxide.

In one embodiment, the film which is composed of the silicon oxide has a thickness of not less than 1 nm and not more than 3 nm.

A semiconductor device fabrication method of the present invention includes the steps of: (a) forming a gate electrode on a substrate; (b) forming a gate insulating film so as to cover an upper surface of the gate electrode; (c) forming a semiconductor layer on the gate insulating film; (d) forming an impurity-containing semiconductor layer on the semiconductor layer; and (e) removing part of the impurity-containing semiconductor layer which extends over the gate electrode and an upper portion of part of the semiconductor layer which extends over the gate electrode, thereby forming an active layer in which part of the semiconductor layer extending over the gate electrode constitutes a first region, such that part of the active layer which constitutes the first region has a smaller thickness than the other part of the active layer, wherein the thickness of the first region is not less than ⅛ and not more than ½ of a thickness of the semiconductor layer.

In one embodiment, the step (c) includes forming the semiconductor layer which includes a first semiconductor layer, an intermediate layer provided on the first semiconductor layer, and a second semiconductor layer provided on the intermediate layer, in this order from the gate insulating film side, and the step (e) includes removing at least the second semiconductor layer under a condition that an etching rate of the second semiconductor layer is higher than an etching rate of the intermediate layer.

In one embodiment, the step (c) includes forming a microcrystalline silicon film which has a crystal grain and an amorphous phase as the first semiconductor layer, and forming a microcrystalline silicon film or an amorphous silicon film as the second semiconductor layer.

In one embodiment, the step (c) includes performing an oxygen plasma treatment, a UV treatment, or an ozone treatment on the first semiconductor layer to oxidize a surface of the first semiconductor layer, thereby forming the intermediate layer.

In one embodiment, the step (c) includes forming the semiconductor layer which includes a first semiconductor layer that is in contact with an upper surface of the gate insulating film, an etching stopper film that covers at least part of the first semiconductor layer extending over the gate electrode, and a second semiconductor layer that extends over the etching stopper film, in this order from the gate insulating film side, and the step (e) includes removing at least the second semiconductor layer under a condition that an etching rate of the second semiconductor layer is higher than an etching rate of the etching stopper film.

A semiconductor device fabrication method of the present invention includes the steps of: (a) forming a gate electrode on a substrate; (b) forming a gate insulating film so as to cover an upper surface of the gate electrode; (c) forming a first semiconductor film on the gate insulating film and removing part of the first semiconductor film extending over the gate electrode, thereby forming a first semiconductor layer which has a trench over the gate electrode; and (d) forming a second semiconductor layer on the first semiconductor layer which has the trench, thereby forming an active layer which is constituted of the first semiconductor layer and the second semiconductor layer, wherein a thickness of the second semiconductor layer is not less than one time and not more than seven times a thickness of the first semiconductor layer.

In one embodiment, the first semiconductor layer is constituted of a microcrystalline silicon film which has a crystal grain and an amorphous phase.

A semiconductor device fabrication method of the present invention includes the steps of: (a) forming a first semiconductor layer on a substrate; (b) forming an impurity-containing semiconductor layer on the first semiconductor layer; (c) forming a trench in the impurity-containing semiconductor layer and the first semiconductor layer to separate the first semiconductor layer and the impurity-containing semiconductor layer into a first region and a second region; (d) forming a second semiconductor layer so as to cover the first region, the second region, and the trench; and (e) forming a gate insulating film so as to cover the second semiconductor layer and forming a gate electrode over the trench such that the gate insulating film is interposed between the gate electrode and the trench, wherein a thickness of the second semiconductor layer is not less than ⅛ and not more than ½ of a thickness of the first semiconductor layer.

In one embodiment, the second semiconductor layer is constituted of a microcrystalline silicon film which has a crystal grain and an amorphous phase.

A semiconductor device fabrication method of the present invention includes the steps of: (a) forming a first semiconductor layer on a substrate; (b) forming a second semiconductor layer on the first semiconductor layer; (c) forming an impurity-containing semiconductor layer on the second semiconductor layer; (d) forming a trench in the impurity-containing semiconductor layer and the second semiconductor layer, thereby forming an active layer which is constituted of the first semiconductor layer and the second semiconductor layer that has the trench; and (e) forming a gate insulating film so as to cover the impurity-containing semiconductor layer and a surface of the trench and forming a gate electrode over the trench such that the gate insulating film is interposed between the gate electrode and the trench, wherein a thickness of the second semiconductor layer is not less than one time and not more than seven times a thickness of the first semiconductor layer.

In one embodiment, the first semiconductor layer is constituted of a microcrystalline silicon film which has a crystal grain and an amorphous phase.

In one embodiment, the microcrystalline silicon film is formed by high density plasma CVD, such as ICP-CVD, surface wave plasma CVD, or ECR-CVD.

### EFFECTS OF THE INVENTION

In a semiconductor device of the present invention, the upper surface of the first region in the active layer is located closer to the substrate than the upper surfaces of the second region and the third region, whereby the value of the OFF current can be reduced as compared with the conventional devices.

In the semiconductor device, the OFF current sharply increases when the gate voltage is negative. However, the distances between the upper surfaces of the ends of the second region and the third region and the upper surface of the first region along the thickness direction of the active layer is set to be not less than one time the thickness of the first region, whereby the increase of the OFF current can be prevented. Also, by setting the distances to be not more than seven times the thickness of the first region, a decrease of the ON current, which would occur due to an increase of the parasitic resistance, can be avoided.

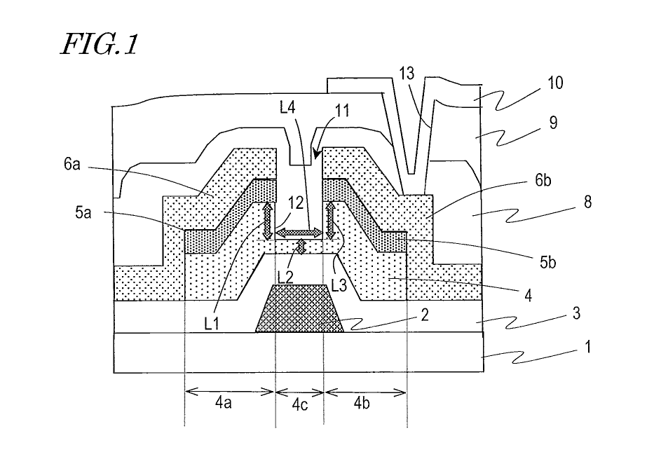

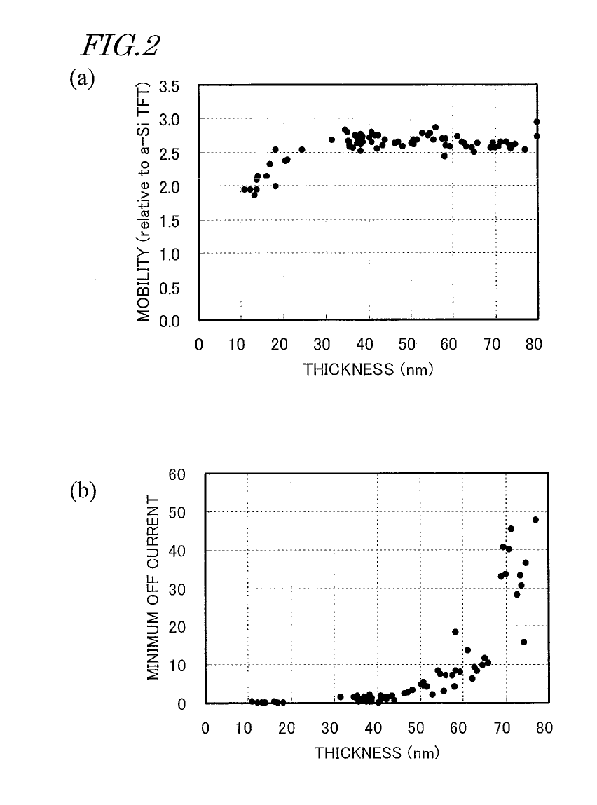

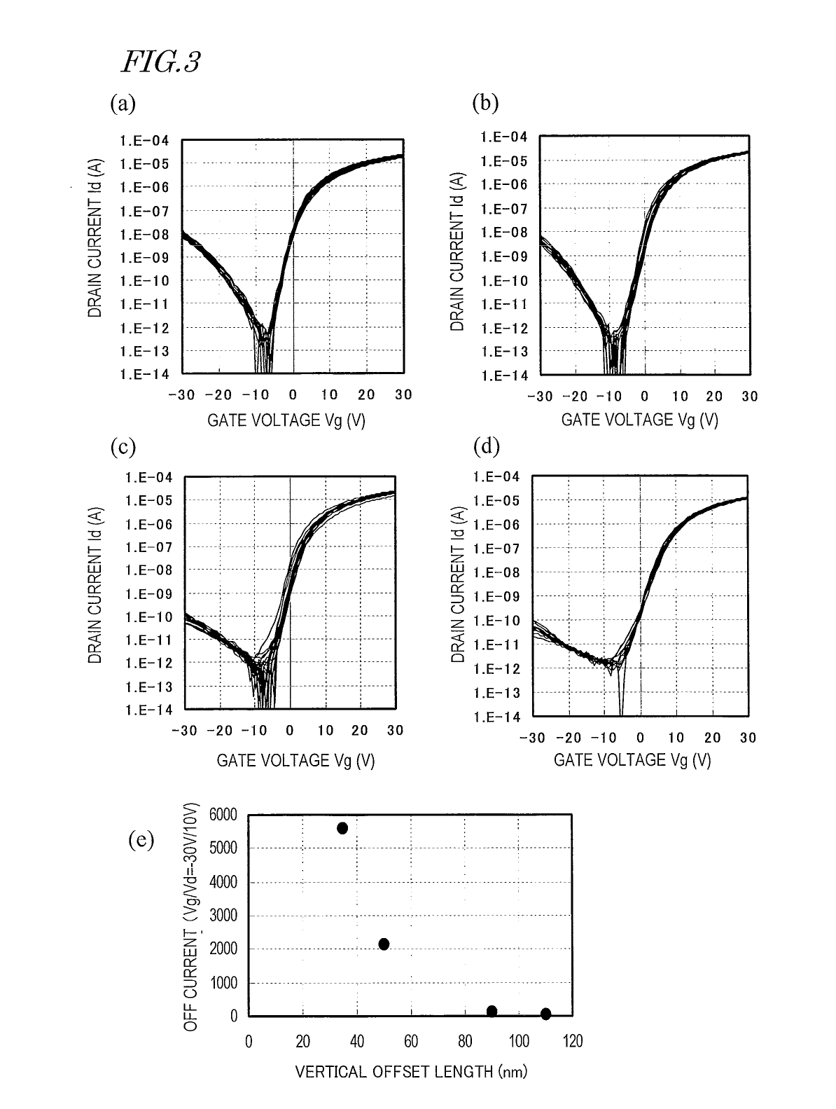

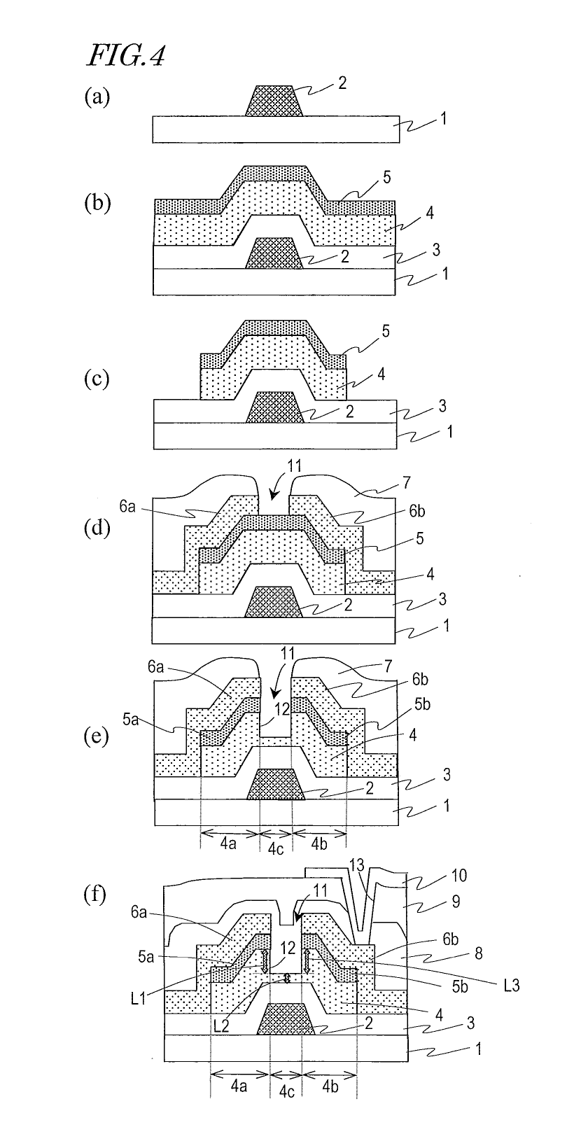

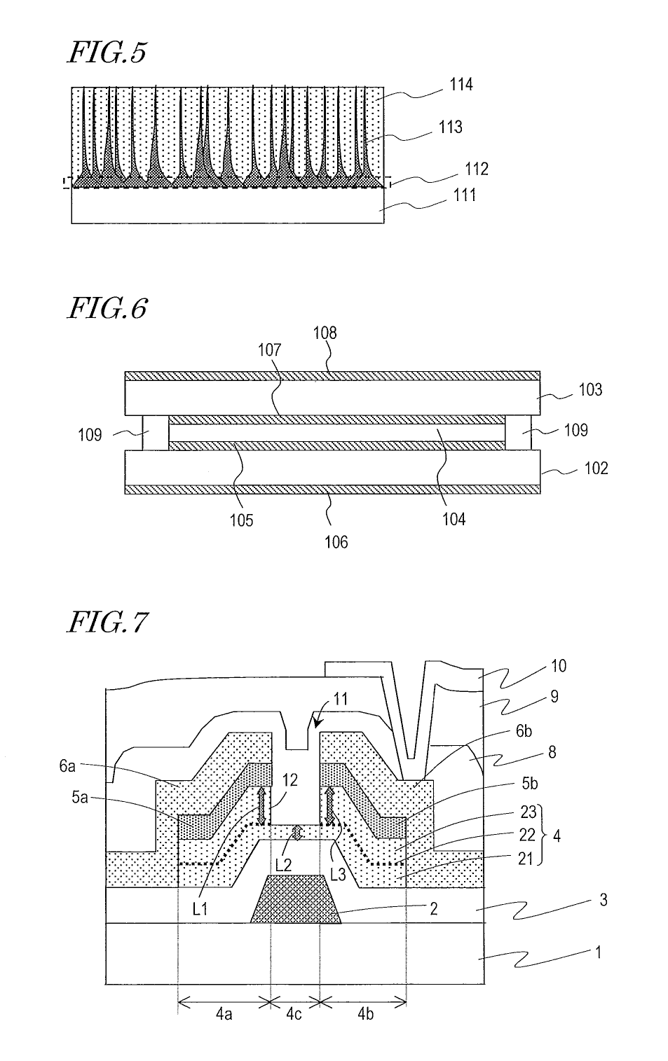

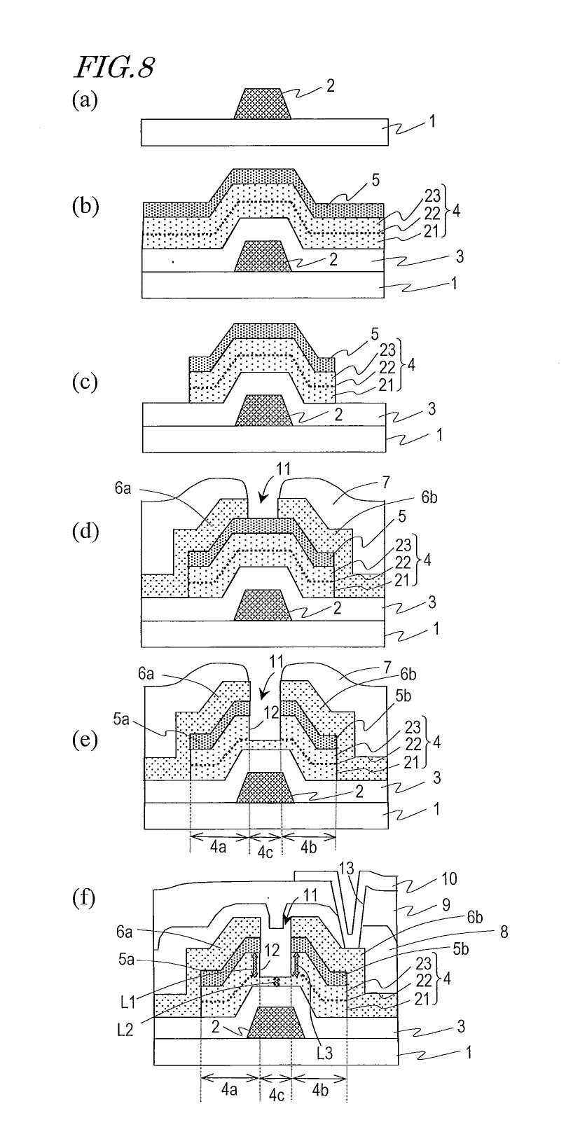

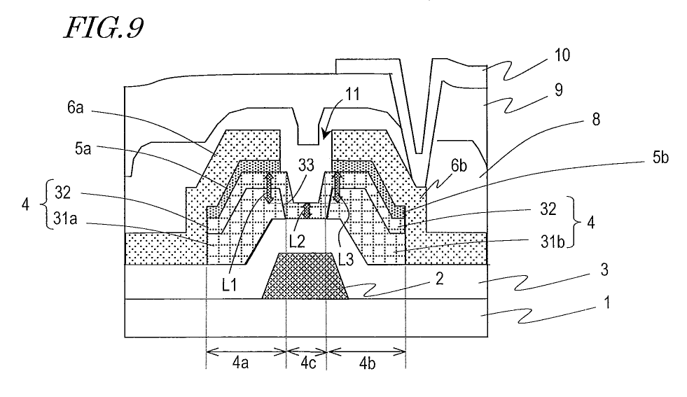

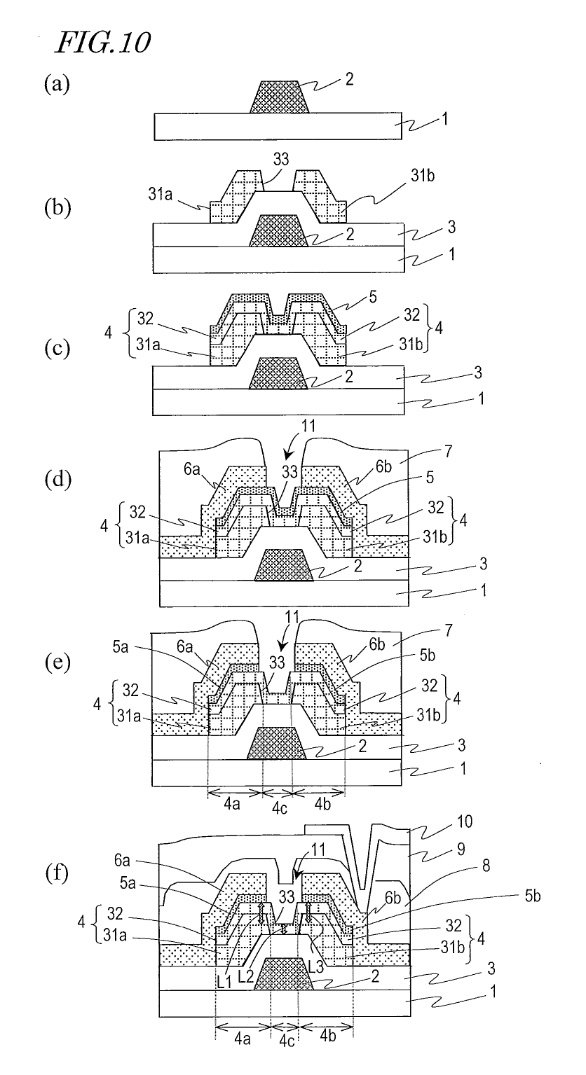

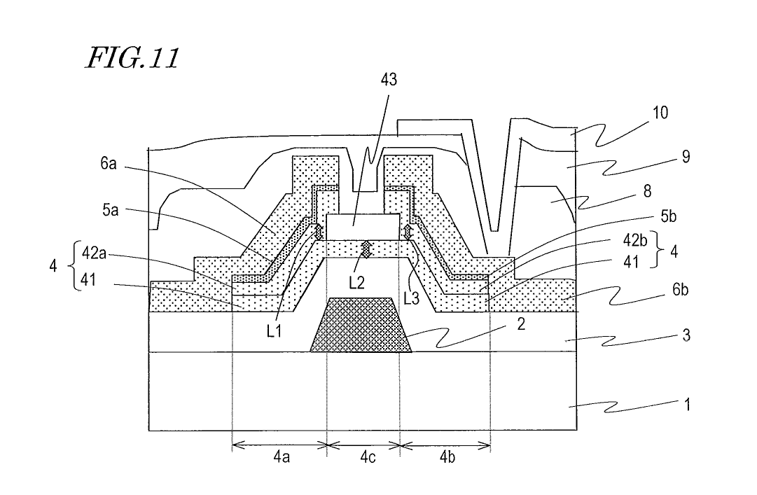

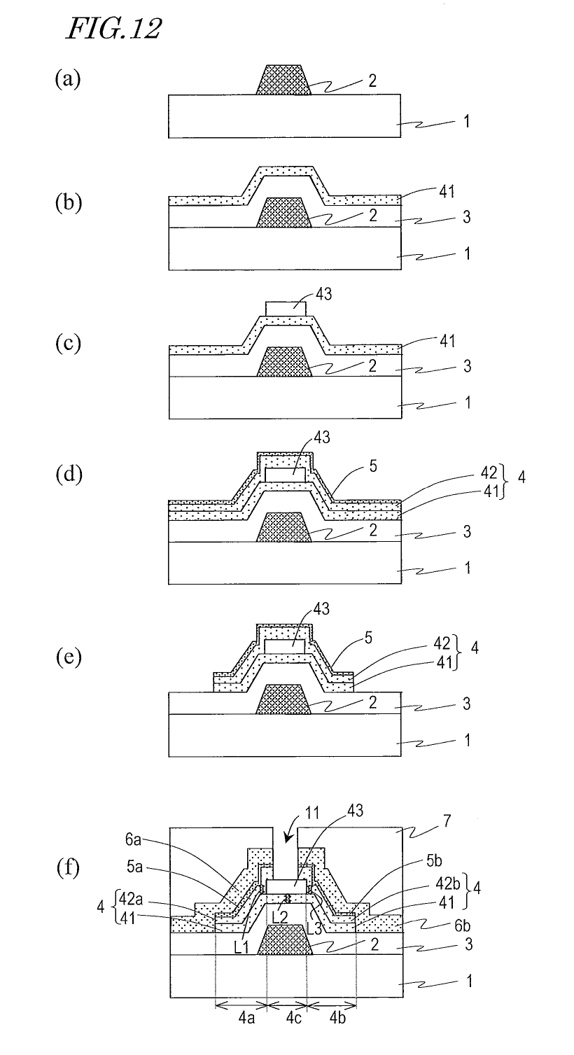

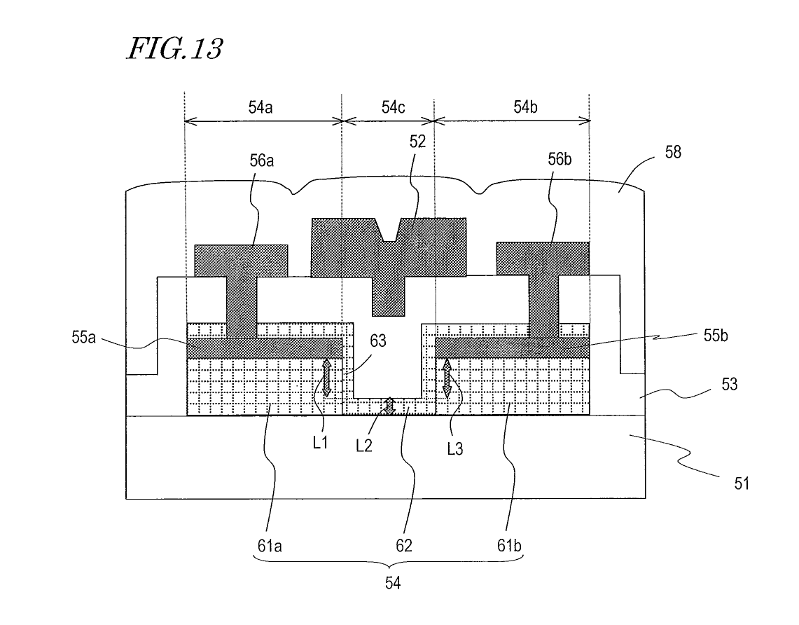

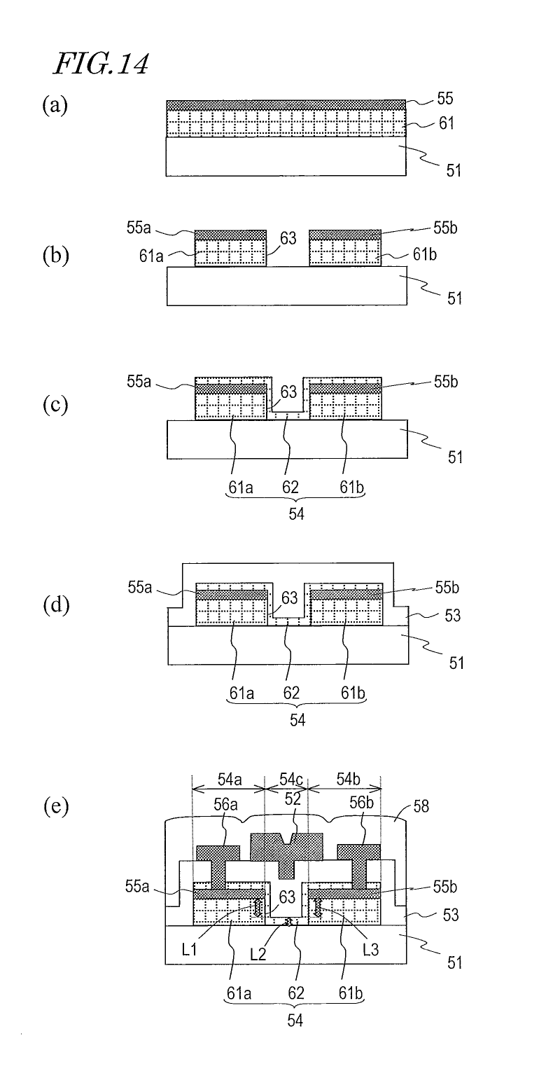

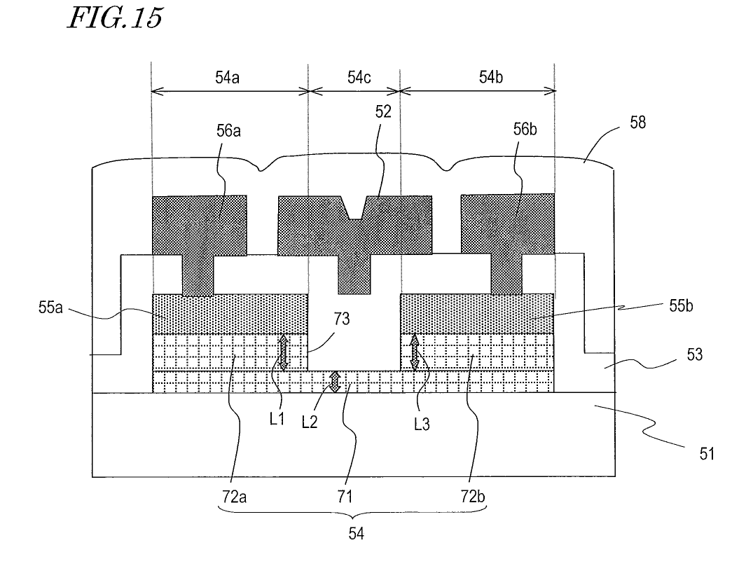

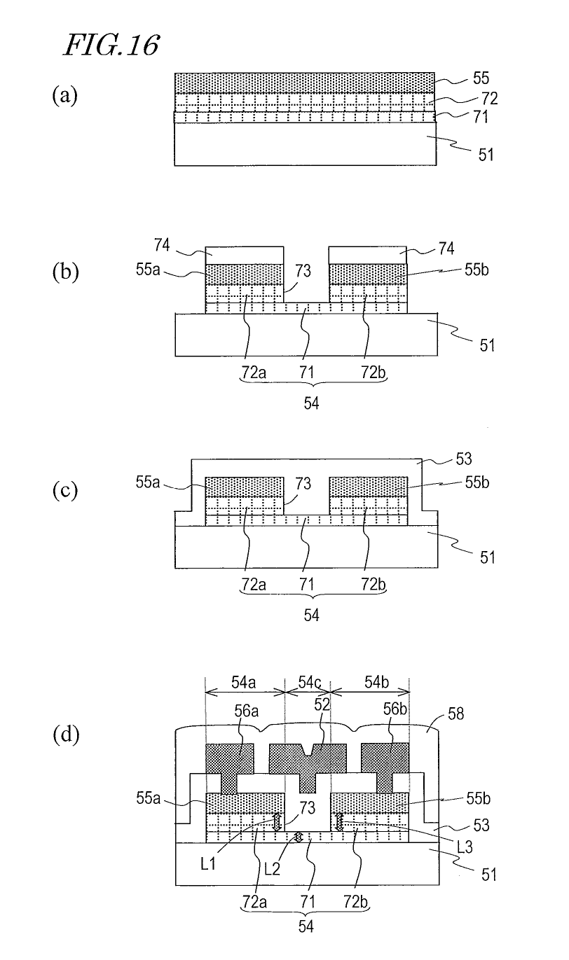

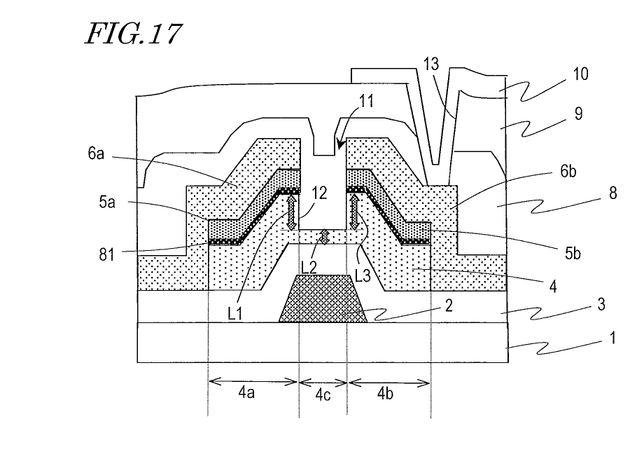

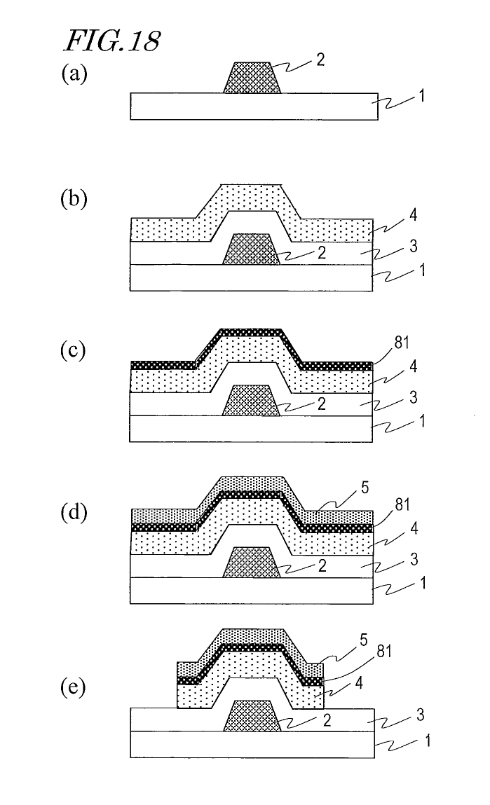

### BRIEF DESCRIPTION OF DRAWINGS

[FIG. 1] A cross-sectional view showing a semiconductor device of embodiment 1.

[FIG. 2] (a) is a graph showing the results of measurement of the mobility of a channel region in the semiconductor device of embodiment 1. (b) is a graph showing the results of measurement of the minimum OFF current in the semiconductor device of embodiment 1.

[FIG. 3] (a) to (e) are graphs that illustrate the relationship between the lengths of the offset portions (L1, L3) and the TFT characteristics.

[FIG. 4] (a) to (f) are cross-sectional views showing the fabrication steps of the semiconductor device of embodiment 1.

[FIG. 5] A diagram schematically showing the state of a crystalline silicon layer and an amorphous silicon layer in a microcrystalline silicon film.

[FIG. 6] A cross-sectional view generally showing a liquid crystal display device which includes the semiconductor device of embodiment 1.

[FIG. 7] A cross-sectional view showing a semiconductor device of embodiment 2.

[FIG. 8] (a) to (f) are cross-sectional views showing the fabrication steps of the semiconductor device of embodiment 2.

[FIG. 9] A cross-sectional view showing a semiconductor device of embodiment 3.

[FIG. 10] (a) to (f) are cross-sectional views showing the fabrication steps of the semiconductor device of embodiment 3.

[FIG. 11] A cross-sectional view showing a semiconductor device of embodiment 4.

[FIG. 12] (a) to (f) are cross-sectional views showing the fabrication steps of the semiconductor device of embodiment 4.

[FIG. 13] A cross-sectional view showing a semiconductor device of embodiment 5.

[FIG. 14] (a) to (e) are cross-sectional views showing the fabrication steps of the semiconductor device of embodiment 5.

[FIG. 15] A cross-sectional view showing a semiconductor device of embodiment 6.

[FIG. 16] (a) to (d) are cross-sectional views showing the fabrication steps of the semiconductor device of embodiment 6.

[FIG. 17] A cross-sectional view showing a semiconductor device of embodiment 7.

[FIG. 18] (a) to (e) are cross-sectional views showing the fabrication steps of the semiconductor device of embodiment 7.

### DESCRIPTION OF THE REFERENCE NUMERALS

1 glass substrate
2 gate electrode
3 gate insulating film
4 semiconductor layer
5 impurity-containing layer
5a, 5b source region, drain region
6 electrode layer
6a, 6b source electrode, drain electrode
7 photoresist
21 first semiconductor layer
22 intermediate layer
23 second semiconductor layer
31a, 31b first semiconductor layer
32 second semiconductor layer
41 first semiconductor layer
42a, 42b second semiconductor layer
43 etching stopper layer
51 glass substrate
52 gate electrode
53 gate insulating film
54 semiconductor layer
55 impurity-containing layer
55a, 55b source region, drain region
56a, 56b source electrode, drain electrode
57 photoresist
61a, 61b first semiconductor layer
62 second semiconductor layer
71 first semiconductor layer
72a, 72b second semiconductor layer
81 layer that contains oxygen

### BEST MODE FOR CARRYING OUT THE INVENTION

Hereinafter, embodiments of a semiconductor device of the present invention are described in detail.

### Embodiment 1

First, the first embodiment of a semiconductor device of the present invention is described with reference to the drawings. FIG. 1 is a cross-sectional view of the semiconductor device of embodiment 1. The semiconductor device of the present embodiment is a TFT having a bottom gate structure, in which a gate electrode is interposed between a semiconductor layer and a glass substrate.

As shown in FIG. 1, the TFT of the present embodiment includes a glass substrate 1 which is an insulator substrate, a gate electrode 2 provided on the glass substrate 1, and a gate insulating film 3 covering the glass substrate and the gate electrode 2. The gate electrode 2 is constituted of, for example, a TaN film or a combination of a Ta film and a TaN film. The gate insulating film 3 is constituted of, for example, a silicon nitride film. A cross-section of the surface of the gate insulating layer 3 has a protuberance which conforms to the cross-sectional shape of the gate electrode 2.

An island-shaped semiconductor layer 4 is provided over the gate electrode 2 such that the gate insulating layer 3 is interposed between the semiconductor layer 4 and the gate electrode 2. The semiconductor layer 4 is composed of microcrystalline silicon which has a crystal grain and an amorphous phase.

Part of the semiconductor layer 4 extending over the gate electrode 2 is raised to a higher level than the other part. At the center of this raised portion, a recess 12 is provided.

Part of the semiconductor layer 4 extending under the bottom surface of the recess 12 has a smaller thickness than the other part. This part is referred to as a first region 4c. Parts of the semiconductor layer 4 on the opposite sides of the first region 4c are respectively referred to as a second region 4a and a third region 4b. With the recess 12 formed therein, the upper surface of the first region 4c is closer to the glass substrate 1 than the upper surfaces of the ends of the second region 4a and the third region 4b adjacent to the first region 4c are.

On the second region 4a, a source region 5a is provided. On the third region 4b, a drain region 5b is provided. The source region 5a and the drain region 5b are composed of amorphous silicon or microcrystalline silicon and contain an n-type impurity, e.g., phosphorus or the like.

The source region 5a is covered with a source electrode 6a. The drain region 5b is covered with a drain electrode 6b. The source electrode 6a and the drain electrode 6b are composed of a conductor, such as a metal. The source electrode 6a and the drain electrode 6b cover not only the upper surfaces of the source region 5a and the drain region 5b but also the side surfaces of the source region 5a and the drain region 5b and the side surfaces of the semiconductor layer 4, and also extends over part of the gate insulating film 3 surrounding the semiconductor layer 4.

The source electrode 6a and the drain electrode 6b are covered with a passivation film 8 which is, for example, a silicon nitride film. The passivation film 8 also covers the inside of the recess 12. The passivation film 8 is covered with a planarizing film 9 which is a transparent resin film.

The planarizing film 9 and the passivation film 8 have a contact hole 13 penetrating through these films. The contact hole 13 reaches the surface of the drain electrode 6b. In the contact hole 13, a transparent electrode 10 is provided which is composed of, for example, ITO (Indium-tin-oxide).

When a voltage higher than the threshold is applied to the gate electrode 2, a current flows from the source region 5a to the drain region 5b via the semiconductor layer 4. In this situation, the current comes out of the source region 5a and flows through the second region 4a to reach the first region 4c, and then passes through the first region 4c and the third region 4b to reach the drain region 5b. Parts of the second region 4a and the third region 4b which are at the side surfaces of the recess 12 are referred to as “offset portions”. The channel length is the sum of the vertical lengths of the offset portions, L1 and L3, and the length of the first region 4c, L4. Note that, if the vertical lengths of the offset portions, L1 and L3, are considerably small as compared with the value of length L4 of the first region 4c, lengths L1 and L3 are negligible, and therefore, the channel length is substantially equal to length L4 of the first region 4c.

In the present embodiment, the upper surface of the first region 4c is closer to the substrate than the upper surfaces of the ends of the second region 4a and the third region 4b adjacent to the first region 4c are. The distances between the upper surfaces of the ends of the second region 4a and the third region 4b and the upper surface of the first region 4c along the thickness direction of the active layer (the lengths of the offset portions) are each independently not less than one time and not more than seven times the thickness of the first region 4c.

In the microcrystalline silicon TFT of the present embodiment, by providing the offset portions on the opposite sides of the first region 4c, the OFF current can be decreased as compared with a case where the offset portions are not provided. Thus, the OFF current can be reduced while the high ON current (high mobility), which is an advantage of the microcrystalline silicon TFT, is secured. Therefore, a high ON/OFF ratio can be realized.

Since a microcrystalline silicon film is formed as the semiconductor layer 4, a TFT can readily be fabricated by a fabrication process which is substantially the same as that commonly applied to a-Si TFTs.

Next, the results of measurement of the characteristics of the TFT of the present embodiment are described. FIG. 2(a) is a graph showing the results of measurement of the mobility of a channel region in the TFT of the present embodiment. FIG. 2(b) is a graph showing the results of measurement of the minimum OFF current in the TFT of the present embodiment. In FIG. 2(a), the abscissa axis represents the thickness (nm) of the first region 4c, and the ordinate axis represents the mobility (relative to the mobility of a-Si TFT as “1”). In FIG. 2(b), the abscissa axis represents the thickness (nm) of the first region 4c, and the ordinate axis represents the minimum OFF current (pA). As seen from FIG. 2(a), when the thickness of the first region 4c is not less than 20 nm, the mobility exhibits a high value which is approximately constant. Also, as seen from FIG. 14(b), when the thickness of the first region 4c is not more than 60 nm, the minimum OFF current falls within a tolerance (15 pA). From these results, it is understood that a high mobility (ON characteristic) and a low OFF current (minimum OFF current) can be achieved at the same time so long as the thickness of the first region 4c is not less than 20 nm and not more than 60 nm.

FIGS. 3(a) to 3(e) are the graphs that illustrate the relationship between the lengths of the offset portions (L1, L3) and the TFT characteristics. FIGS. 3(a), 3(b), 3(c), and 3(d) show the TFT characteristics for the offset lengths of 35 nm, 50 nm, 90 nm, and 110 nm, respectively. In FIGS. 3(a) to 3(d), the abscissa axis represents the gate voltage Vg (V), and the ordinate axis represents the drain current Id (A). Note that the TFT used in this measurement has the channel length (L) of 3 μm and the channel width (W) of 20 μm. The channel length refers to the distance between the source electrode 6a and the drain electrode 6b in the cross-section shown in FIG. 1 (the length of the first region 4c, i.e., L4). The channel width refers to the length of the source electrode 6a and the drain electrode 6b along a direction perpendicular to the cross-section shown in FIG. 1.

Drain voltage Vd is 10 V. As seen from FIG. 3(e), when the offset length is 90 nm or 110 nm, the OFF current (drain current Id at Vg=−30 V) is small. FIG. 3(e) is a graph in which the OFF currents obtained in FIGS. 3(a) to 3(d) are plotted for the respective lengths of the offset portions (L1, L3). As seen from FIG. 3(e), when the lengths of the offset portions are 70 nm or more, the OFF current falls within the tolerance. If the offset portions are too long, the parasitic resistance becomes large. As such, the lengths of the offset portions are preferably not less than 70 nm and not more than 140 nm.

From the above data, a preferred ratio between the thickness of the first region 4c (L2) and the lengths of the offset portions (L1, L3) can be calculated. Specifically, the lengths of the offset portions are preferably not more than seven times the thickness of the first region 4c because the minimum thickness of the first region 4c is 20 nm and the maximum lengths of the offset portions are 140 nm. Also, the lengths of the offset portions are preferably not less than one time the thickness of the first region 4c because the maximum thickness of the first region 4c is 60 nm and the minimum lengths of the offset portions are 60 nm.

Next, a method for fabricating a semiconductor device of the present embodiment is described with reference to FIGS. 4(a) to 4(f). FIGS. 4(a) to 4(f) are cross-sectional views showing the fabrication steps of the semiconductor device of embodiment 1.

First, referring to FIG. 4(a), the gate electrode 2 is formed on the glass substrate 1. Specifically, a TaN film, a Ta film, and a TaN film are formed by sputtering in this order on the surface of the glass substrate 1. Thereafter, unnecessary part is removed by dry etching to form the gate electrode 2. Here, the etching advances while a photoresist (not shown) is gradually shrunk by introducing oxygen into the etching gas. As a result, the gate electrode 2 has such a tapered shape that the side surfaces of the gate electrode 2 form an angle of 45° relative to the surface of the glass substrate 1.

Then, referring to FIG. 4(b), the gate insulating film 3, the semiconductor layer 4 and an impurity-containing layer 5 are formed in this order on the gate electrode 2. Here, the thickness of the semiconductor layer 4 is in the range of not less than 90 nm and not more than 200 nm (e.g., 130 nm), and the thickness of the impurity-containing layer 5 is 30 nm. The impurity-containing layer 5 may be microcrystalline silicon or may be amorphous silicon.

The gate insulating film 3 and the impurity-containing layer 5 are formed by a parallel plate type CVD apparatus. The gate insulating film 3, the semiconductor layer 4, and the impurity-containing layer 5 are continuously formed in vacuum using a multi-chamber type apparatus.

Specifically, the gate insulating film 3 of a silicon nitride film (SiNₓ film) having a thickness of about 400 nm is formed by plasma CVD. Then, the semiconductor layer 4 of a microcrystalline silicon film is formed by high-density plasma CVD (ICP-CVD, surface wave plasma CVD, or ECR-CVD). Then, the impurity-containing layer 5 is formed by plasma CVD in a gas atmosphere which contains an n-type impurity, such as phosphorus.

The gate insulating film 3 and the impurity-containing layer 5 can be formed under the same film formation conditions as those of the fabrication process of a common a-Si TFT. On the other hand, the semiconductor layer 4 may be formed using SiH₄ and H₂ as the material gases for the plasma CVD with the flow rate ratio of SiH₄ and H₂, SiH₄/H₂, is about 1/20, and the pressure being about 1.33 Pa (10 mTorr). The range of the pressure during film formation is preferably not less than 0.133 Pa and not more than 13.3 Pa. The range of SiH₄/H₂ is preferably not less than 1/30 and not more than 1. During the formation of the semiconductor layer 4, the temperature of the glass substrate 1 is about 300° C. Before the formation of the semiconductor layer 4, a surface treatment by plasma may be performed on the gate insulating film 3. The pressure during the surface treatment is about 1.33 Pa.

Then, referring to FIG. 4(c), the semiconductor layer 4 and the impurity-containing layer 5 are photolithographically patterned so as to have an island shape. By performing dry etching as the etching, a very small shape can be formed. The etching gas used herein contains chlorine (Cl₂) with which the selection ratio relative to the silicon nitride film of the gate insulating film 3 easy. During the etching, the etching portion is monitored by an end point detector (EPD). The etching is continued till the gate insulating film 3 is exposed.

Then, referring to FIG. 4(d), an electrode layer is formed by sputtering on the island-shaped impurity-containing layer 5. The electrode layer includes an Al film having the thickness of 100 nm and a Mo film having the thickness of 100 nm.

Thereafter, a photoresist 7 is formed so as to cover the electrode layer. In the photoresist 7, an opening 11 is formed such that the electrode layer is exposed at a position above the gate electrode 2. This photoresist 7 is used as a mask for performing etching such that the opening 11 penetrates through the electrode layer. As a result, the source electrode 6a and the drain electrode 6b are formed on the opposite sides of the opening 11. Note that the etching employed for formation of the opening 11 may be wet etching, so that only the electrode layer can be selectively etched. The etchant used may be an SLA etchant.

Then, referring to FIG. 4(e), dry etching is performed with the photoresist 7 being left unremoved, whereby the exposed impurity-containing layer 5 is etched to form the source region 5a and the drain region 5b. In this step, etching is continued even after the exposed portion of the impurity-containing layer 5 is completely removed, whereby part of the semiconductor layer 4 is also removed so that the bottom surface of the opening 11 reaches to a position lower than the upper surface of the semiconductor layer 4. As a result, the thickness of the semiconductor layer 4 at a position under the opening 11 (the first region 4c) is smaller than the other part. Thereafter, when the thickness of the first region 4c reaches a desired value, the etching is stopped before the opening 11 penetrates through the semiconductor layer 4. Specifically, the etching is stopped when the thickness of the first region 4c becomes not less than ⅛ and not more than ½ of the thickness of the semiconductor layer 4. Thereafter, the photoresist 7 is removed. Through the above steps, the recess 12 can be formed in the semiconductor layer 4.

Then, referring to FIG. 4(f), the passivation film 8 of a silicon nitride film is formed by plasma CVD so as to cover the upper surfaces of the source electrode 6a and the drain electrode 6b. In this step, the inside of the opening 11 is filled with the passivation film 8, so that the source region 5a and the drain region 5b are insulated from each other by the passivation film 8, and the source electrode 6a and the drain electrode 6b are also insulated from each other by the passivation film 8.

Subsequently, the planarizing film 9 of a resin film (JAS film) is formed so as to cover the passivation film 8. Then, at a position above the drain electrode 6b, a contact hole 13 is formed so as to penetrate through the planarizing film 9 and the passivation film 8. Thereafter, an ITO film is formed by sputtering over the surfaces of the planarizing film 9 and the contact hole 13 and is patterned to form the transparent electrode 10. Through the above steps, the semiconductor device of the present embodiment can be obtained.

In a common microcrystalline silicon TFT, the OFF current sharply increases when the gate voltage is negative (to −30 V). However, by setting lengths L1, L3 of the offset portions so as to be not less than one time thickness L2 of the first region 4c, the increase in the OFF current can be prevented. Also, by setting the thickness of the first region 4c so as to be not less than ⅛ and not more than ½ of the thickness of the semiconductor layer 4 before the formation of the recess 12. Thus, the decrease in the ON current, which would occur due to an increase in parasitic resistance, can be avoided.

(Regarding Microcrystalline Silicon Film)

The semiconductor layer 4 of the microcrystalline silicon film has a structure mixedly containing a crystalline silicon phase and an amorphous silicon phase. Whether or not the semiconductor layer 4 is a microcrystalline silicon film can be determined by a Raman spectroscopic measurement. The crystalline silicon exhibits a sharp peak at the wavelength of 520 cm⁻¹, whereas the amorphous silicon exhibits a broad peak at the wavelength of 480 cm⁻¹. Since the microcrystalline silicon film mixedly contains both crystalline silicon and amorphous silicon, the Raman spectroscopic measurement results in a spectrum which has the highest peak at the wavelength of 520 cm⁻¹ and a broad peak on the lower wavelength side. The crystallization rate can be compared in terms of the intensity ratio of the peak at 520 cm⁻¹ and the peak at 480 cm⁻¹.

When a silicon film is formed by solid phase crystallization (SPC) or laser crystallization, the above-described peak intensity ratio is about 30 to 80. From this result, it can be inferred that the formed film did not substantially contain an amorphous component, and the formed film is a polycrystalline silicon film.

For example, the peak intensity ratio of the microcrystalline silicon film formed by high density plasma CVD (520 cm⁻¹/480 cm⁻¹) is about 2 to 20. Although the proportion of the crystalline silicon phase in the microcrystalline silicon film can be increased by modifying the conditions of the high density plasma CVD, a complete crystalline silicon film cannot be formed. Forming a silicon layer by high density plasma CVD substantially ensures that the formed silicon layer mixedly contains the crystalline silicon phase and the amorphous silicon phase.

Forming a semiconductor film 4 by high density plasma CVD enables formation of the film at a low temperature. Thus, a substrate which is not suitable to a high temperature treatment, such as a glass substrate, a plastic substrate, or the like, can be adopted as the above-described glass substrate 1, and the productivity thereof can be improved.

FIG. 5 schematically shows the state of the crystalline silicon phase and the amorphous silicon phase in the microcrystalline silicon film. The microcrystalline silicon film shown in FIG. 5 includes, at the interface with a glass substrate 111, an incubation layer 112 which is an amorphous phase having a thickness of several nanometers. Over the incubation layer 112, the crystalline silicon phase 114 is provided. The crystalline silicon phase 114 has the shape of a column extending vertically to the surface of the glass substrate 111. The gap between the adjacent crystalline silicon phases 114 is provided with a grain boundary 113 extending from the incubation layer 112. If the diameter of the cross section of the crystalline silicon phase 114 is not less than 5 nm and not more than 40 nm, the crystalline cross section is sufficiently small for the device size, and therefore, the device can have uniform characteristics. According to the tendency of the film formation process, the incubation layer 112, which is the amorphous phase, readily grows in the early part of the formation process of the microcrystalline silicon film; however, the proportion of the crystalline silicon phase 114 gradually increases as the film formation advances. This incubation layer 112 is a precursor which lasts until the growth of the microcrystalline silicon film, and includes many voids in the film and therefore exhibits a very low mobility.

Using the high density plasma CVD can brings about a considerable improvement in the crystallization rate of the microcrystalline silicon film, particularly the crystallization rate and density in the early part of the film formation process. Specifically, using high density plasma CVD enables the incubation layer 112 of FIG. 5 to have a smaller thickness and enables the volume fraction of the amorphous phase to be not less than 5% and not more than 40%. Using high density plasma CVD also enables the flow rate ratio of SiH₄ and H₂, i.e., SiH₄/H₂, to be not less than 1/30 and not more than 1/1. Therefore, the supply rate of SiH₄ can be increased, and the film formation rate can be increased.

On the other hand, in a common plasma CVD apparatus of a so-called parallel plate type, it is difficult to obtain a crystalline silicon phase in the early part of the film formation process, so that a portion of the film which has been formed in the early part, and which has a thickness of about 50 nm, results in the incubation layer 112. To form the microcrystalline silicon film using this parallel plate type plasma CVD apparatus, it is necessary to set the SiH₄/H₂ ratio to about 1/300 to 1/100. In this case, however, the supply rate of SiH₄ decreases, and the film formation speed also decreases.

In view of the above results, in embodiment 1, in the formation of the semiconductor layer 4, a high density plasma CVD (ICP-CVD, surface wave CVD, or ECR-CVD) apparatus is preferably used. Further, before the formation of the semiconductor layer 4, a surface treatment with H₂ plasma is performed, whereby the crystallinity in the early part of the film formation process can be further improved.

Next, a liquid crystal display device which includes the TFT of the present embodiment is described. FIG. 6 is a cross-sectional view generally showing a liquid crystal display device which includes the TFT of embodiment 1. As shown in FIG. 6, the liquid crystal display device of the present embodiment includes an active matrix substrate 102 which is a semiconductor device and which is a first substrate, a liquid crystal layer 104 which is a display medium layer, and a counter substrate 103 which is a second substrate that opposes the active matrix substrate 102 via the liquid crystal layer 104. The liquid crystal layer 104 is sealed by a sealant 109 provided between the active matrix substrate 102 and the counter substrate 103.

A surface of the active matrix substrate 102 which is closer to the liquid crystal layer 104 is provided with an alignment film 105. A surface of the counter substrate 103 which is closer to the liquid crystal layer 104 is provided with an alignment film 107. On the other hand, the other surface of the active matrix substrate 102 which is opposite to the liquid crystal layer 104 is provided with a polarizer 106. The other surface of the counter substrate 103 which is opposite to the liquid crystal layer 104 is provided with a polarizer 108.

The active matrix substrate 102 includes a plurality of pixels, although not shown. TFTs, each of which is a switching element such as shown in FIG. 1, are provided in respective one of the pixels. The active matrix substrate 102 is also provided with a driver IC (not shown) for driving and controlling the respective TFTs.

The counter substrate 103 is provided with a color filter and a common electrode of ITO, although not shown.

The active matrix substrate 102 shown in FIG. 6 is formed by: forming the TFTs, wires, etc., on a glass substrate; thereafter forming the alignment film 105; and attaching the polarizer 106 and connecting the driver IC (not shown) and other elements. The liquid crystal display device is configured such that the alignment of liquid crystal molecules in the liquid crystal layer 104 is controlled by the TFTs in respective pixels for performing a desired display.

### Embodiment 2

Next, the second embodiment of a semiconductor device of the present embodiment is described. FIG. 7 is a cross-sectional view showing the semiconductor device of embodiment 2. The semiconductor device of the present embodiment is a TFT that has a bottom gate structure in which a gate electrode is interposed between a semiconductor layer and a glass substrate.

As shown in FIG. 7, the TFT of the present embodiment has a semiconductor layer 4. The semiconductor layer 4 includes a first semiconductor layer 21 constituted of a microcrystalline silicon film, an intermediate layer 22 that is a silicon oxide formed on the first semiconductor layer 21, and a second semiconductor layer 23 which is provided on the intermediate layer 22 and which is a microcrystalline silicon film or amorphous silicon film. The thickness of the first semiconductor layer 21 is not less than 20 nm and not more than 60 nm. The thickness of the intermediate layer 22 is not less than 1 nm and not more than 3 nm. The thickness of the second semiconductor layer 23 is not less than 60 nm and not more than 140 nm.

The first region 4c of the semiconductor layer 4 is constituted of the first semiconductor layer 21 and does not include the second semiconductor layer 23. The second region 4a and the third region 4b of the semiconductor layer 4 is constituted of parts of the first semiconductor layer 21 which are provided on opposite sides of the first region 4c, the intermediate layer 22 overlying the first semiconductor layer 21, and the second semiconductor layer 23 overlying the intermediate layer 22.

In the present embodiment, the upper surface of the first region 4c is closer to the glass substrate 1 than the upper surfaces of the ends of the second region 4a and the third region 4b adjacent to the first region 4c are. The distances between the upper surfaces of the ends of the second region 4a and the third region 4b and the upper surface of the first region 4c along the thickness direction of the active layer (the lengths of the offset portions) are each independently not less than one time and not more than seven times the thickness of the first region 4c. The other elements are the same as those of embodiment 1, and therefore, the descriptions thereof are herein omitted.

The microcrystalline silicon TFT of the present embodiment can provide the effects that are substantially the same as those of the first embodiment. In addition, by providing the intermediate layer 22 between the first semiconductor layer 21 and the second semiconductor layer 23, selective etching of the second semiconductor layer 23 is facilitated. Thus, the thickness of the first semiconductor layer 21 (the first region 4c), L2, and the thicknesses of the offset portions, L1, L3, can surely be controlled.

Next, a method for fabricating a TFT of embodiment 2 is described. FIGS. 8(a) to 8(f) are cross-sectional views showing the fabrication steps of the semiconductor device of embodiment 2. Here, only part of the fabrication steps which is different from embodiment 1 is described in detail.

First, referring to FIG. 8(a), the gate electrode 2, which is constituted of a TaN film, a Ta film, and a TaN film, is formed by sputtering on the glass substrate 1.

Then, referring to FIG. 8(b), the gate insulating film 3 of a silicon nitride film is formed on the gate electrode 2 by plasma CVD. Thereafter, the semiconductor layer 4 is formed on the gate insulating film 3. In the present embodiment, the first semiconductor layer 21, the intermediate layer 22, and the second semiconductor layer 23 are formed as the semiconductor layer 4. Specifically, first, by performing a high density plasma CVD (ICP-CVD, surface wave plasma CVD, or ECR-CVD), the first semiconductor layer 21 of a microcrystalline silicon film is formed on the gate insulating film 3. Thereafter, an oxygen plasma treatment, an ozone treatment, or a UV treatment is performed to oxidize the surface of the first semiconductor layer 21, whereby the intermediate layer 22 of a silicon oxide is formed. Then, by performing another high density plasma CVD, the second semiconductor layer 23 of a microcrystalline silicon film is formed on the intermediate layer 22. Note that, if the second semiconductor layer 23 is not constituted of a microcrystalline silicon film but an amorphous silicon film, for example, a common plasma CVD may be performed. Subsequently, the impurity-containing layer 5 is formed on the semiconductor layer 4 by performing a plasma CVD in a gas atmosphere that contains an n-type impurity, such as phosphorus or the like.

Then, referring to FIG. 8(c), the semiconductor layer 4 and the impurity-containing layer 5 are photolithographically patterned so as to have an island shape.

Then, referring to FIG. 8(d), an electrode layer, which is constituted of an Al film and a Mo film, is formed by sputtering on the island-shaped impurity-containing layer 5. Thereafter, a photoresist 7 is formed so as to cover the electrode layer. In the photoresist 7, an opening 11 is formed such that the electrode layer is exposed at a position above the gate electrode 2. The photoresist 7 is used as a mask for performing an etching such that the opening 11 penetrates through the electrode layer 6. As a result, the source electrode 6a and the drain electrode 6b are formed on the opposite sides of the opening 11.

Then, referring to FIG. 8(e), dry etching is performed with the photoresist 7 being left unremoved, whereby the exposed impurity-containing layer 5 is etched. As a result, the impurity-containing layer 5 is separated into the source region 5a and the drain region 5b. The etching is allowed to advance even after the opening 11 has penetrated through the impurity-containing layer 5, thereby removing the second semiconductor layer 23.

In this etching process, the etching rate of the second semiconductor layer 23 and the etching rate of the intermediate layer 22 are different because the second semiconductor layer 23 is a microcrystalline silicon layer or an amorphous silicon layer and the intermediate layer 22 is a silicon oxide. Thus, by using an etching gas which is composed such that the etching rate of the second semiconductor layer 23 is higher than that of the intermediate layer 22, the etching can be stopped at the intermediate layer 22. For example, when a chlorine gas is used in the etching, the etching selection ratio of the microcrystalline silicon film or the amorphous silicon film relative to the silicon oxide is about 10 to 20.

In the TFT of the present embodiment, the thickness of the first region 4c is not less than ⅛ and not more than ½ of the thickness of the semiconductor layer 4 before the formation of the recess 12. To obtain the thickness ratio in this range, in the step shown in FIG. 8(c), the second semiconductor layer 23 is preferably formed so as to have a thickness which is not less than one time and not more than seven times the thickness of the first semiconductor layer 21.

The resultant structure is treated with hydrogen fluoride such that the silicon oxide remaining in the opening 11 can be readily removed. If the intermediate layer 22 of the silicon oxide is interposed between the first semiconductor layer 21 and the second semiconductor layer 23, the intermediate layer 22 itself deteriorates the electric conduction characteristics. However, by performing a thermal treatment at 200 to 300° C. so as not to affect the TFT characteristics, electric conduction can be established between the first semiconductor layer 21 and the second semiconductor layer 23. This is because the silicon oxide produced by plasma oxidation, UV treatment, or ozone treatment is very thin and porous. Since the density of the silicon oxide produced by a common thermal treatment (thermal oxidation film) is high, electric conduction cannot be established by a thermal treatment at 200 to 300° C. The thermal treatment for establishing electric conduction between the first semiconductor layer 21 and the second semiconductor layer 23 may be performed at any time after the formation of the first semiconductor layer 21 and the second semiconductor layer 23.

Thereafter, referring to FIG. 8(f), a passivation film 8, a planarizing film 9, and a transparent electrode 10 are formed to complete the fabrication of the TFT.

### Embodiment 3

Next, a semiconductor device of the third embodiment of the present invention is described. FIG. 9 is a cross-sectional view showing the semiconductor device of embodiment 3. The semiconductor device of the present embodiment is a TFT that has a bottom gate structure in which a gate electrode is interposed between a semiconductor layer and a glass substrate.

As shown in FIG. 9, the TFT of the present embodiment has a semiconductor layer 4. The semiconductor layer 4 includes first semiconductor layers 31a, 31b constituted of a microcrystalline silicon film or an amorphous silicon film, and a second semiconductor layer 32 constituted of a microcrystalline silicon film. The first semiconductor layers 31a, 31b are respectively provided on the opposite sides of the gate electrode 2. A portion between the first semiconductor layers 31a, 31b, i.e., a portion extending over the gate electrode 2, is provided with a trench 33. The second semiconductor layer 32 covers the upper surfaces of the first semiconductor layers 31a, 31b as well as the surface of the trench 33.

With the above arrangement of the first semiconductor layers 31a, 31b and the second semiconductor layer 32, the first region 4c of the semiconductor layer 4 (a portion of the semiconductor layer 4 extending over the gate electrode 2) is constituted of the second semiconductor layer 32. The second region 4a and the third region 4b of the semiconductor layer 4 are constituted of the first semiconductor layers 31a, 31b and the second semiconductor layer 32 provided on the first semiconductor layers 31a, 31b. The thickness of the first semiconductor layers 31a, 31b is not less than 60 nm and not more than 140 nm. The thickness of the second semiconductor layer 32 is not less than 20 nm and not more than 80 nm.

In the TFT of the present embodiment, the thickness of the second semiconductor layer 32 (the thickness of the first region 4c: L2) is not less than one time and not more than seven times the length of the offset portion (the distance between the upper surfaces of the second semiconductor layer 32 at the ends of the second region 4a and the third region 4b and the upper surface of the second semiconductor layer 32 in the first region 4c along the thickness direction of the active layer), i.e., the thickness of the first semiconductor layers 31a, 31b (L1, L3). The other elements of the structure are the same as those of embodiment 1, and therefore, the descriptions thereof are herein omitted.

Next, a method for fabricating the TFT of embodiment 3 is described. FIGS. 10(a) to 10(f) are cross-sectional views showing the fabrication steps of the semiconductor device of embodiment 3. Here, only part of the fabrication steps which is different from embodiment 1 is described in detail.

First, referring to FIG. 10(a), the gate electrode 2, which has a layered structure constituted of a TaN film, a Ta film, and a TaN film, is formed by sputtering on the glass substrate 1.

Then, referring to FIG. 10(b), the gate insulating film 3 of a silicon nitride film is formed on the gate electrode 2 by plasma CVD. Thereafter, the first semiconductor layers 31a, 31b are formed on the gate insulating film 3. Specifically, a microcrystalline silicon film or an amorphous silicon film is formed over the entire surface of the gate insulating film 3 and then patterned such that the trench 33 is formed at a position above the gate electrode 2 and that the first semiconductor layers 31a, 31b are formed on opposite sides of the trench 33.

Then, referring to FIG. 10(c), the second semiconductor layer 32 of a microcrystalline silicon film is formed over the surfaces of the first semiconductor layers 31a, 31b and the surface of the trench 33. Further, the impurity-containing layer 5 is formed on the second semiconductor layer 32 by performing a plasma CVD in a gas atmosphere that contains an n-type impurity, such as phosphorus or the like.

Then, referring to FIG. 10(d), an electrode layer, which is constituted of an Al film and a Mo film, is constituted of sputtering on the island-shaped impurity-containing layer 5. Thereafter, a photoresist 7 is formed so as to cover the electrode layer. In the photoresist 7, an opening 11 is formed such that the electrode layer is exposed at a position above the gate electrode 2. The photoresist 7 is used as a mask for performing an etching such that, first, the opening 11 penetrates through the electrode layer. As a result, the source electrode 6a and the drain electrode 6b are formed on the opposite sides of the opening 11.

Then, referring to FIG. 10(e), dry etching is performed with the photoresist 7 being left unremoved, whereby the exposed impurity-containing layer 5 is etched. As a result, the impurity-containing layer 5 is separated into the source region 5a and the drain region 5b.

Thereafter, referring to FIG. 10(f), a passivation film 8, a planarizing film 9, and a transparent electrode 10 are formed to complete the fabrication of the TFT.

In the present embodiment, substantially the same effects as those of embodiment 1 can be produced. In addition, the first semiconductor layers 31a, 31b are formed as separate parts so that the thickness of the second semiconductor layer 32 can be equal to the thickness of the first region 4c. With this arrangement, the thickness of the second semiconductor layer 32 (the first region 4c), L2, and the thicknesses of the offset portions, L1, L3, can be surely controlled.

In the TFT fabrication method of the present embodiment, the etching amount required for formation of the opening 11 can be advantageously reduced. Specifically, in embodiment 1, in order to form the trench 12, the etching need to be performed by the amount of the thickness of the impurity-containing layer 5 (e.g., 40 nm) and the thicknesses of the offset portions (L1, L3: e.g., 60 to 140 nm), for example, 110 to 180 nm. In this case, if the etching distribution is ±10%, the thickness varies in the range of ±11 to 18 nm. On the other hand, in the present embodiment, the etching may be performed by the amount of the thickness of the impurity-containing layer 5 (e.g., 40 nm) plus alpha. That is, the removed portion may be only about 50 to 70 nm. In this case, if the etching distribution is ±10%, the thickness varies in the range of ±5 to 7 nm. Thus, the thickness can be controlled with smaller errors.

### Embodiment 4

Next, a semiconductor device of the fourth embodiment of the present invention is described. FIG. 11 is a cross-sectional view showing the semiconductor device of embodiment 4. The semiconductor device of the present embodiment is a TFT that has a bottom gate structure in which a gate electrode is interposed between a semiconductor layer and a glass substrate.

As shown in FIG. 11, in the TFT of the present embodiment, a first semiconductor layer 41 of a microcrystalline silicon film is provided on a gate insulating film 3. On part of the first semiconductor layer 41 extending over the gate electrode 2, an etching stopper layer 43 of a silicon nitride film is provided. On the etching stopper layer 43 and the first semiconductor layer 41, second semiconductor layers 42a, 42b of a microcrystalline silicon film or an amorphous silicon film are provided. The first semiconductor layer 41 and the second semiconductor layers 42a, 42b constitute a semiconductor layer 4.

In the present embodiment, the thicknesses of the second semiconductor layers 42a, 42b (L1, L3) are not less than one time and not more than seven times the thickness of the first semiconductor layer 41 (thickness L2 of the first region 4c). In other words, the distances between the upper surfaces of the ends of the second region 4a and the third region 4b and the upper surface of the first region 4c along the thickness direction of the second semiconductor layers 42a, 42b are each independently not less than one time and not more than seven times the thickness of the first region 4c. Herein, “the ends of the second region 4a and the third region 4b” do not refers to parts of the second semiconductor layers 42a which cover the side surfaces of the etching stopper layer 43, but refer to parts of the second semiconductor layers 42a which cover the upper surface of the first semiconductor layer 41.

For example, preferably, the thickness of the first semiconductor layer 41 is not less than 20 nm and not more than 60 nm, and the thickness of the second semiconductor layers 42a, 42b is not less than 20 nm and not more than 140 nm. The other elements are the same as those of embodiment 1, and therefore, the descriptions thereof are herein omitted.

In the present embodiment, substantially the same effects as those of embodiment 1 can be produced. In addition, the etching is performed with the etching stopper layer 43, so that the etching can be stopped more surely. Therefore, the thickness of the first semiconductor layer 41 (the first region 4c), L2, and the thicknesses of the offset portions, L1, L3, can surely be controlled.

Next, a fabrication method of embodiment 4 is described. FIGS. 12(a) to 12(f) are cross-sectional views showing the fabrication steps of the semiconductor device of embodiment 4.

First, referring to FIG. 12(a), the gate electrode 2, which has a layered structure constituted of a TaN film, a Ta film, and a TaN film, is formed by sputtering on the glass substrate 1.

Then, referring to FIG. 12(b), the gate insulating film 3 of a silicon nitride film is formed on the gate electrode 2 by plasma CVD. On the gate insulating film 3, the first semiconductor layer 41 of a microcrystalline silicon film is provided.

Then, referring to FIG. 12(c), a silicon nitride film is formed on the first semiconductor layer 41 by plasma CVD and then patterned to form the etching stopper layer 43 on part of the first semiconductor layer 41 extending over the gate electrode 2.

Then, referring to FIG. 12(d), a second semiconductor layer 42 is formed so as to cover the first semiconductor layer 41 and the etching stopper layer 43, and an impurity-containing layer 5 is formed on the second semiconductor layer 42.

Then, referring to FIG. 12(e), the first semiconductor layer 41, the second semiconductor layer 42, and the impurity-containing layer 5 are patterned to have an island shape.

Then, referring to FIG. 12(f), an electrode layer is formed so as to cover the upper surfaces of the impurity-containing layer 5, the second semiconductor layer 42, and the first semiconductor layer 41 which have the island shape, and thereafter, a photoresist 7 is formed on the electrode layer. In the photoresist 7, an opening 11 is formed such that the electrode layer is exposed at a position above the gate electrode 2. The photoresist 7 is used as a mask for performing an etching such that, first, the opening 11 penetrates through the electrode layer. As a result, the source electrode 6a and the drain electrode 6b are formed on the opposite sides of the opening 11. Thereafter, the etching is allowed to advance till the etching stopper layer 43 is reached, whereby the source region 5a and the drain region 5b are formed, and the second semiconductor layers 42a, 42b are also formed.

Thereafter, although not shown, the photoresist 7 is removed, and a passivation film 8, a planarizing film 9, and a transparent electrode 10 are formed, whereby a TFT can be formed.

### Embodiment 5

Next, a semiconductor device of the fifth embodiment of the present invention is described. FIG. 13 is a cross-sectional view showing the semiconductor device of embodiment 5. The semiconductor device of the present embodiment is a TFT that has a top gate structure (staggered structure), whereas the semiconductor devices of embodiments 1 to 4 have the bottom gate structure.

As shown in FIG. 13, in the TFT of the present embodiment, first semiconductor layers 61a, 61b of a microcrystalline silicon film or an amorphous silicon film are provided on a glass substrate 51, which is an insulator substrate, such that the first semiconductor layers 61a, 61b are separated from each other. The thickness of the first semiconductor layers 61a, 61b is not less than 60 nm and not more than 140 nm. A trench 63 is provided between the first semiconductor layers 61a, 61b. A source region 55a is provided on the first semiconductor layer 61a, and a drain region 55b is provided on the second semiconductor layer 61b. The source region 55a and the drain region 55b are composed of amorphous silicon or microcrystalline silicon and contain an n-type impurity, e.g., phosphorus, or the like.

The surfaces of the source region 55a, the drain region 55b, and the trench 63 are covered with a second semiconductor layer 62. The second semiconductor layer 62 is constituted of a microcrystalline silicon film or an amorphous silicon film having a thickness of not less than 20 nm and not more than 60 nm. The first semiconductor layers 61a, 61b and the second semiconductor layer 62 constitute a semiconductor layer 54. Part of the second semiconductor layer 62 which covers the surface of the trench 63 is referred to as a first region 54c. The first semiconductor layer 61a is referred to as a second region 54a. The first semiconductor layer 61b is referred to as a third region 54b. Note that part of the second semiconductor layer 62 which covers the upper surfaces of the source region 55a and the drain region 55b does not function as an active layer through which an electric current flows, and is therefore not included in any of the first region 54c, the second region 54a, and the third region 54b of the semiconductor layer 54.

In the present embodiment, the upper surface of the first region 54c (herein, the upper surface of part of the second semiconductor layer 62 which covers the bottom surface of the trench 63) is closer to the glass substrate 1 than the upper surfaces of the ends of the second region 54a and the third region 54b adjacent to the first region 54c (the upper surfaces of the first semiconductor layers 61a, 61b) are. The vertical distance between the upper surface of the first semiconductor layer 61a in the second region 54a and the upper surface of the second semiconductor layer 62 in the first region 54c (length L1 of the offset portion) is not less than one time and not more than seven times the thickness of the second semiconductor layer 62 (thickness L2 of the first region 4c). At the same time, the vertical distance between the upper surface of the first semiconductor layer 61b in the third region 54b and the upper surface of the second semiconductor layer 62 in the first region 54c (length L3 of the offset portion) is not less than one time and not more than seven times the thickness of the second semiconductor layer 62 (thickness L2 of the first region 4c).

The upper surface of the second semiconductor layer 62 is covered with a gate insulating film 53 of a silicon nitride film. On part of the gate insulating film 53 which opposes the first region 54c, a gate electrode 52 of an Al/Mo layered structure (Mo is the lower layer) is provided. On the other hand, on part of the gate insulating film 53 which opposes the second region 54a, a source electrode 56a of an Al/Mo layered structure (Mo is the lower layer) is provided. The source electrode 56a penetrates through the gate insulating film 53 and the second semiconductor layer 62 and is in contact with the source region 55a. On part of the gate insulating film 53 which opposes the third region 54b, a drain electrode 56b of an Al/Mo layered structure (Mo is the lower layer) is provided. The drain electrode 56b penetrates through the gate insulating film 53 and the second semiconductor layer 62 and is in contact with the drain region 55b. The upper surfaces of the gate insulating film 53, the gate electrode 52, the source electrode 56a, and the drain electrode 56b are covered with a protective film 58.

The microcrystalline silicon TFT of the present embodiment includes offset portions so that the OFF current can be reduced as compared with a case where the offset portions are not provided. Thus, the OFF current can be reduced while the large ON current (high mobility), which is an advantage of the microcrystalline silicon TFT, is secured. Therefore, a high ON/OFF ratio can be realized.

In the microcrystalline silicon TFT, the OFF current sharply increases when the gate voltage is negative (to −30 V). However, by setting lengths L1, L3 of the offset portions so as to be not less than one time thickness L2 of the first region 4c, the increase in the OFF current can be prevented. Also, by setting lengths L1, L3 of the offset portions so as to be not more than seven times thickness L2 of the first region 4c, the decrease in the ON current, which would occur due to an increase in parasitic resistance, can be avoided. Specifically, so long as the lengths of the offset portions (L1, L3) are not less than 60 nm and not more than 140 nm, a high mobility (ON characteristic) and a low OFF current (minimum OFF current) can be achieved at the same time.

Since the microcrystalline silicon film is formed as the semiconductor layer 54, a TFT can easily be fabricated using substantially the same fabrication process as that employed for common a-Si TFTs.

The value of the thickness of the first semiconductor layers 61a, 61b minus the thickness of the second semiconductor layer 62 can be considered as being equal to the thickness of the offset portion (L1, L3), and the thickness of the second semiconductor layer 62 can be considered as being equal to the thickness of the first region 4c (L2). Thus, these thicknesses can be controlled more surely.

Next, a TFT fabrication method of the present embodiment is described with reference to FIGS. 14(a) to 14(e). FIGS. 14(a) to 14(e) are cross-sectional views showing the fabrication steps of the semiconductor device of embodiment 5.

First, referring to FIG. 14(a), by performing a high density plasma CVD (ICP-CVD, surface wave plasma CVD, or ECR-CVD) on the glass substrate 51, a microcrystalline silicon film 61 is formed. Here, an amorphous silicon film may be formed instead of the microcrystalline silicon film 61. In this case, for example, a plasma CVD may be performed.

Thereafter, an impurity-containing layer 55 is formed on the microcrystalline silicon film 61 by performing a plasma CVD in a gas atmosphere that contains an n-type impurity, such as phosphorus or the like.

Then, referring to FIG. 14(b), a resist mask (not shown) is formed on the impurity-containing layer 55, and patterning is performed such that the trench 63 is formed in the impurity-containing layer 55 and the microcrystalline silicon film 61. As a result, on opposite sides of the trench 63, the first semiconductor layers 61a, 61b and the source region 55a and drain region 55b are formed.

Then, referring to FIG. 14(c), by performing a high density plasma CVD (ICP-CVD, surface wave plasma CVD, or ECR-CVD), the second semiconductor layer 62 of a microcrystalline silicon film is formed so as to cover the first semiconductor layers 61a, 61b and the trench 63. In the present embodiment, the thickness of the second semiconductor layer is not less than ⅛ and not more than ½ of the thickness of the first semiconductor layers 61a, 61b.

Then, referring to FIG. 14(d), the gate insulating film 53 of a silicon nitride film is formed on the second semiconductor layer 62 by performing a plasma CVD.

Then, referring to FIG. 14(e), the gate electrode 52, the source electrode 56a, and the drain electrode 56b are formed on the gate insulating film 53, and the protective film 58 of a silicon nitride film is formed on these electrodes. Through the above steps, the TFT can be fabricated.

### Embodiment 6

Next, a semiconductor device of the sixth embodiment of the present invention is described. FIG. 15 is a cross-sectional view showing the semiconductor device of embodiment 6. The semiconductor device of the present embodiment is a TFT that has a top gate structure (staggered structure).

As shown in FIG. 15, in the TFT of the present embodiment, a first semiconductor layer 71, which is a microcrystalline silicon film having a thickness of not less than 20 nm and not more than 60 nm, is provided on a glass substrate 51 that is an insulator substrate. On the first semiconductor layer 71, second semiconductor layers 72a, 72b are provided. The second semiconductor layers 72a, 72b are separated from each other by a trench 73. The second semiconductor layers 72a, 72b are constituted of a microcrystalline silicon film or an amorphous silicon film having a thickness of not less than 60 nm and not more than 140 nm. The first semiconductor layer 71 and the second semiconductor layers 72a, 72b constitute the semiconductor layer 54. Part of the first semiconductor layer 71 lying under the bottom surface of the trench 73 is referred to as a first region 54c. The second semiconductor layer 72a and part of the first semiconductor layer 71 lying under the second semiconductor layer 72a are referred to as the second region 54a. The second semiconductor layer 72b and part of the first semiconductor layer 71 lying under the second semiconductor layer 72b are referred to as a third region 54b.

In the present embodiment, the upper surface of the first region 54c is closer to the glass substrate 51 than the upper surfaces of the ends of the second region 54a and the third region 54b adjacent to the first region 54c are. The vertical distance between the upper surface of the second semiconductor layer 72a in the second region 54a and the upper surface of the first semiconductor layer 71 in the first region 54c (length L1 of the offset portion) is not less than one time and not more than seven times the thickness of the first semiconductor layer 71 (thickness L2 of the first region 54c). At the same time, the vertical distance between the upper surface of the second semiconductor layer 72b in the third region 54b and the upper surface of the first semiconductor layer 71 in the first region 54c (length L3 of the offset portion) is not less than one time and not more than seven times the thickness of the first semiconductor layer 71 (thickness L2 of the first region 54c).

A source region 55a is provided on the second semiconductor layer 72a, and a drain region 55b is provided on the second semiconductor layer 72b. On the source region 55a and drain region 55b and part of the first semiconductor layer 71 at the bottom surface of the trench 73, the gate insulating film 53 of a silicon nitride film is provided.

On part of the gate insulating film 53 which opposes the first region 54c, a gate electrode 52 of an Al/Mo layered structure (Mo is the lower layer) is provided. On the other hand, on part of the gate insulating film 53 which opposes the second region 54a, a source electrode 56a of an Al/Mo layered structure (Mo is the lower layer) is provided. The source electrode 56a penetrates through the gate insulating film 53 and the second semiconductor layers 72a, 72b and is in contact with the source region 55a. On part of the gate insulating film 53 which opposes the third region 54b, a drain electrode 56b of an Al/Mo layered structure (Mo is the lower layer) is provided. The drain electrode 56b penetrates through the gate insulating film 53 and the second semiconductor layers 72a, 72b and is in contact with the drain region 55b. The upper surfaces of the gate insulating film 53, the gate electrode 52, the source electrode 56a, and the drain electrode 56b are covered with a protective film 58 of a silicon nitride film.

The microcrystalline silicon TFT of the present embodiment includes offset portions so that the OFF current can be reduced as compared with a case where the offset portions are not provided. Thus, the OFF current can be reduced while the large ON current (high mobility), which is an advantage of the microcrystalline silicon TFT, is secured. Therefore, a high ON/OFF ratio can be realized.

In the microcrystalline silicon TFT, the OFF current sharply increases when the gate voltage is negative (to −30 V). However, by setting the lengths of the offset portions, L1, L3, so as to be not less than one time thickness L2 of the first region 4c, the increase in the OFF current can be prevented. Also, by setting the lengths of the offset portions, L1, L3, so as to be not more than seven times thickness L2 of the first region 4c, the decrease in the ON current, which would occur due to an increase in parasitic resistance, can be avoided. Specifically, so long as the lengths of the offset portions (L1, L3) are not less than 60 nm and not more than 140 nm, a high mobility (ON characteristic) and a low OFF current (minimum OFF current) can be achieved at the same time.

Since the microcrystalline silicon film is formed as the semiconductor layer 54, a TFT can easily be fabricated using substantially the same fabrication process as that employed for common a-Si TFTs.

Next, a TFT fabrication method of the present embodiment is described with reference to FIGS. 16(a) to 16(d). FIGS. 16(a) to 16(d) are cross-sectional views showing the fabrication steps of the semiconductor device of embodiment 6.

First, referring to FIG. 16(a), by performing a high density plasma CVD (ICP-CVD, surface wave plasma CVD, or ECR-CVD) on the glass substrate 51, the first semiconductor layer 71 of a microcrystalline silicon film is formed. Then, by performing a high density plasma CVD (ICP-CVD, surface wave plasma CVD, or ECR-CVD), the second semiconductor layer 72 of a microcrystalline silicon film is formed on the first semiconductor layer 71. Here, an amorphous silicon film may be formed as the second semiconductor layer 72. Thereafter, the impurity-containing layer 55 is formed on the second semiconductor layer 72. Then, referring to FIG. 16(b), a resist mask 74 is formed on the impurity-containing layer 55, and patterning is performed such that the trench 73 is formed in the impurity-containing layer 55 and the second semiconductor layer 72. As a result, on opposite sides of the trench 73, the source region 55a and the drain region 55b are formed while the second semiconductor layers 72a, 72b are also formed. Thereafter, the resist mask 74 is removed.

Then, referring to FIG. 16(c), the gate insulating film 53 is formed so as to cover the surfaces of the source region 55a, the drain region 55b, and the trench 73.

Then, referring to FIG. 16(d), the gate electrode 52 is formed over the trench 73 such that the gate insulating film 53 is interposed between the gate electrode 52 and the trench 73, while the source electrode 56a and the drain electrode 56b are formed. Through the above steps, the TFT can be fabricated.

In the case where a top gate type TFT is formed as in embodiments 5 and 6, the crystallization rate is likely to increase as the thickness of the microcrystalline silicon film increases. Since that high crystallization rate region is provided on a side closer to the interface with the gate insulating film, the mobility can be increased as compared with the bottom gate structure.

### Embodiment 7

Next, a semiconductor device of the seventh embodiment of the present invention is described. FIG. 17 is a cross-sectional view showing the semiconductor device of embodiment 7. The semiconductor device of the present embodiment is a TFT that has a bottom gate structure in which a gate electrode is interposed between a semiconductor layer and a glass substrate.

As shown in FIG. 17, in the TFT of the present embodiment, a layer 81 that contains oxygen is provided between the semiconductor layer 4 and the source region 5a and drain region 5b. The oxygen-containing layer 81 contains oxygen at a higher concentration than its surrounding region (the semiconductor layer 4, the source region 5a, and the drain region 5b). Specifically, the oxygen-containing layer preferably contains oxygen at not less than 1×10²⁰ atoms/cm³ and not more than 1×10²² atoms/cm³. More preferably, the oxygen-containing layer 81 contains oxygen at not less than 1×10²¹ atoms/cm³. The thickness of the oxygen-containing layer 81 is preferably not less than 1 nm and not more than 30 nm, for example, although it depends on the oxygen concentration of the oxygen-containing layer 81. If it is not less than 1 nm, the OFF current can be reduced more surely. On the other hand, if it exceeds 30 nm, there is a probability that the electric resistance of the oxygen-containing layer 81 becomes excessively large so that the ON current decreases.

In the present embodiment, the upper surface of the first region 4c is closer to the glass substrate 1 than the upper surfaces of the ends of the second region 4a and the third region 4b adjacent to the first region 4c are. The distances between the upper surfaces of the ends of the second region 4a and the third region 4b and the upper surface of the first region 4c along the thickness direction of the active layer (the lengths of the offset portions) are each independently not less than one time and not more than seven times the thickness of the first region 4c. The other elements are the same as those of embodiment 1, and therefore, the descriptions thereof are herein omitted.

The TFT of the present embodiment can provide the effects that are substantially the same as those of embodiment 1. In addition, by providing the oxygen-containing layer 81 that has a high electric resistance in the middle of the current path between the source region 5a and the drain region 5b, the OFF current can be further reduced, so that the ON/OFF ratio can be improved.

Next, a method for forming the oxygen-containing layer 81 is described. FIGS. 18(a) to 18(e) are cross-sectional views showing the fabrication steps of the semiconductor device of embodiment 7. Here, only part of the fabrication steps which is different from embodiment 1 is described in detail.

First, referring to FIG. 18(a), the gate electrode 2 is formed on the glass substrate 1, and thereafter, the gate insulating film 3 and the semiconductor layer 4 are formed as shown in FIG. 18(b).

Then, the substrate is removed out of a chamber and is exposed to air that contains oxygen. During the exposure, the semiconductor layer 4 is kept at a temperature not less than 15° C. and not more than 30° C. The semiconductor layer 4 is exposed to the air for 24 hours to 48 hours. As a result, a surface of the semiconductor layer 4 is oxidized to form the oxygen-containing layer 81 as shown in FIG. 18(c).

Then, referring to FIG. 18(d), the impurity-containing layer 5 is formed on the oxygen-containing layer 81. Thereafter, referring to FIG. 18(e), the semiconductor layer 4, the oxygen-containing layer 81, and the impurity-containing layer 5 are shaped into an island.

Thereafter, substantially the same steps as those of embodiment 1 are performed to obtain the TFT as shown in FIG. 17.

In the step of forming the semiconductor layer 4, the source region 5a, and the drain region 5b, oxygen is introduced into the semiconductor layer 4, the source region 5a, and the drain region 5b even without intent to do so, because a very small amount of oxygen is contained in the chamber. Oxygen may come into these layers in the middle of the fabrication steps or after the completion of the fabrication. However, in the step of forming the oxygen-containing layer 81, the surface of the semiconductor layer 4 is intentionally exposed to oxygen, and accordingly, a larger amount of oxygen is supplied to the surface of the semiconductor layer 4 than the other regions. Therefore, the oxygen concentration of the oxygen-containing layer 81 is higher than those of the surrounding regions.

The semiconductor layer 4 and the oxygen-containing layer 81 may be formed in succession by CVD in the same chamber.

In the above, embodiments 1 to 7 has been described with the examples of TFT which are to be used in the active matrix substrate 102 (shown in FIG. 6) of liquid crystal display devices. However, the present invention is not limited to these examples, but may be applied to, for example, an active matrix substrate of an organic EL display device. Also, the present invention is applicable not only to TFTs that are provided as switching elements of the pixels but also to other devices including, for example, switching elements of a gate driver or an organic EL display device.

### INDUSTRIAL APPLICABILITY

As described above, the present invention is very effective in the case where commonly-employed a-Si TFTs provide insufficient mobility, and is applicable to, for example, large size liquid crystal display devices, organic EL display devices, etc.

1. A semiconductor device, comprising:
a substrate;
an island-shaped active layer provided on the substrate, the active layer including a first region, a second region, and a third region, and the second region and the third region being provided on opposite sides of the first region;
a first contact layer and a second contact layer, the first contact layer being in contact with an upper surface of the second region of the active layer, and the second contact layer being in contact with an upper surface of the third region of the active layer;
a first electrode electrically coupled to the second region via the first contact layer;
a second electrode electrically coupled to the third region via the second contact layer; and
a gate electrode which is provided to oppose the first region via a gate insulating film for controlling the conductivity of the first region,
wherein an upper surface of the first region is closer to the substrate than upper surfaces of ends of the second region and the third region adjacent to the first region are, and
distances between the upper surfaces of the ends of the second region and the third region and the upper surface of the first region along a thickness direction of the active layer are each independently not less than one time and not more than seven times a thickness of the first region,
the distances are not less than 60 nm and not more than 140 nm, and
the thickness of the first region is not less than 20 nm and not more than 60 nm.

2. The semiconductor device of claim 1, wherein at least the first region is constituted of a microcrystalline silicon film which has a crystal grain and an amorphous phase.

3. The semiconductor device of claim 2, wherein a volume fraction of the amorphous phase in the microcrystalline silicon film is not less than 5% and not more than 40%.

4. (canceled)

5. The semiconductor device of claim 1, wherein the ends of the second region and the third region which are adjacent to the first region are composed of a microcrystalline silicon.

6. The semiconductor device of claim 1, wherein the ends of the second region and the third region which are adjacent to the first region are composed of an amorphous silicon.

7. The semiconductor device of claim 1, wherein the gate electrode is provided between the active layer and the substrate.

8. The semiconductor device of claim, wherein the gate electrode is provided on a side of the active layer which is opposite to the substrate.

9. The semiconductor device of claim 1, wherein
the active layer includes a first active layer, an intermediate layer, and a second active layer in this order from a substrate side,
the first region is constituted of the first active layer and does not include the second active layer, and
the second region and the third region are constituted of the first active layer, the intermediate layer, and the second active layer.

10. The semiconductor device of claim 9, wherein
the first active layer and the second active layer are silicon layers, and
the intermediate layer is a film composed of a silicon oxide.

11. The semiconductor device of claim 10, wherein the film which is composed of the silicon oxide has a thickness of not less than 1 nm and not more than 3 nm.

12. A method for fabricating a semiconductor device, comprising the steps of:
(a) forming a gate electrode on a substrate;
(b) forming a gate insulating film so as to cover an upper surface of the gate electrode;
(c) forming a semiconductor layer on the gate insulating film;
(d) forming an impurity-containing semiconductor layer on the semiconductor layer; and
(e) removing part of the impurity-containing semiconductor layer which extends over the gate electrode and an upper portion of part of the semiconductor layer which extends over the gate electrode, thereby forming an active layer in which part of the semiconductor layer extending over the gate electrode constitutes a first region, such that part of the active layer which constitutes the first region has a smaller thickness than the other part of the active layer,
wherein the thickness of the first region is not less than ⅛ and not more than ½ of a thickness of the semiconductor layer.

13. The method of claim 12, wherein
the step (c) includes forming the semiconductor layer which includes a first semiconductor layer, an intermediate layer provided on the first semiconductor layer, and a second semiconductor layer provided on the intermediate layer, in this order from the gate insulating film side, and
the step (e) includes removing at least the second semiconductor layer under a condition that an etching rate of the second semiconductor layer is higher than an etching rate of the intermediate layer.

14. The method of claim 13, wherein the step (c) includes
forming a microcrystalline silicon film which has a crystal grain and an amorphous phase as the first semiconductor layer, and
forming a microcrystalline silicon film or an amorphous silicon film as the second semiconductor layer.

15. The method of claim 14, wherein the step (c) includes performing an oxygen plasma treatment, a UV treatment, or an ozone treatment on the first semiconductor layer to oxidize a surface of the first semiconductor layer, thereby forming the intermediate layer.

16. The method of claim 12, wherein
the step (c) includes forming the semiconductor layer which includes a first semiconductor layer that is in contact with an upper surface of the gate insulating film, an etching stopper film that covers at least part of the first semiconductor layer extending over the gate electrode, and a second semiconductor layer that extends over the etching stopper film, in this order from the gate insulating film side, and
the step (e) includes removing at least the second semiconductor layer under a condition that an etching rate of the second semiconductor layer is higher than an etching rate of the etching stopper film.

17. A method for fabricating a semiconductor device, comprising the steps of:
(a) forming a gate electrode on a substrate;
(b) forming a gate insulating film so as to cover an upper surface of the gate electrode;
(c) forming a first semiconductor film on the gate insulating film and removing part of the first semiconductor film extending over the gate electrode, thereby forming a first semiconductor layer which has a trench over the gate electrode; and
(d) forming a second semiconductor layer on the first semiconductor layer which has the trench, thereby forming an active layer which is constituted of the first semiconductor layer and the second semiconductor layer,
wherein a thickness of the second semiconductor layer is not less than one time and not more than seven times a thickness of the first semiconductor layer.

18. The method of claim 17, wherein the first semiconductor layer is constituted of a microcrystalline silicon film which has a crystal grain and an amorphous phase.

19. A method for fabricating a semiconductor device, comprising the steps of:
(a) forming a first semiconductor layer on a substrate;
(b) forming an impurity-containing semiconductor layer on the first semiconductor layer;
(c) forming a trench in the impurity-containing semiconductor layer and the first semiconductor layer to separate the first semiconductor layer and the impurity-containing semiconductor layer into a first region and a second region;
(d) forming a second semiconductor layer so as to cover the first region, the second region, and the trench; and
(e) forming a gate insulating film so as to cover the second semiconductor layer and forming a gate electrode over the trench such that the gate insulating film is interposed between the gate electrode and the trench,
wherein a thickness of the second semiconductor layer is not less than ⅛ and not more than ½ of a thickness of the first semiconductor layer.

20. The method of claim 19, wherein the second semiconductor layer is constituted of a microcrystalline silicon film which has a crystal grain and an amorphous phase.

21. A method for fabricating a semiconductor device, comprising the steps of:
(a) forming a first semiconductor layer on a substrate;
(b) forming a second semiconductor layer on the first semiconductor layer;
(c) forming an impurity-containing semiconductor layer on the second semiconductor layer;
(d) forming a trench in the impurity-containing semiconductor layer and the second semiconductor layer, thereby forming an active layer which is constituted of the first semiconductor layer and the second semiconductor layer that has the trench; and
(e) forming a gate insulating film so as to cover the impurity-containing semiconductor layer and a surface of the trench and forming a gate electrode over the trench such that the gate insulating film is interposed between the gate electrode and the trench,
wherein a thickness of the second semiconductor layer is not less than one time and not more than seven times a thickness of the first semiconductor layer.

22. The method of claim 21, wherein the first semiconductor layer is constituted of a microcrystalline silicon film which has a crystal grain and an amorphous phase.

23. The method of claim 18, 20, or 22, wherein the microcrystalline silicon film is formed by high density plasma CVD, such as ICP-CVD, surface wave plasma CVD, or ECR-CVD.
